(19) United States
(12) Patent Application Publication
(10) Pub. No.: US 2011/0290305 A1
(43) Pub. Date: Dec. 1, 2011

(54) Cabled matrix for cantilevered photovoltaic solar panel arrays, apparatus and deployment systems

(76) Inventors: Steve Hoffmann, New York, NY (US); George Weiner, Florida, NY (US); Steven Hoffmann, Warwick, NY (US)

(21) Appl. No.: 12/802,061

(22) Filed: May 28, 2010

(51) Int. Cl. H01L 31/048

(52) U.S. Cl. 136/251

(57) ABSTRACT

A cable reinforced matrix to support a solar panel array comprising array bracing beams which define a perimeter including longitudinal array bracing beams and latitudinal array bracing beams with coupling apertures at various points along the latitudinal array bracing beams; cable couplings at opposite points along the latitudinal array bracing beams; cabling traversing the latitudinal array bracing beams; solar panels atop the cabling; longitudinal I-beams; latitudinal I-beams; interpanel I-beam(s); grommets along the cabling; grommet clips; grommet clip fasteners; panel fasteners; columns at either end of the longitudinal array bracing beams; a first cantilever support post extending from the column to the distal portion of the longitudinal array bracing beam; a second cantilever support post extending from the column to the proximal portion of the longitudinal array bracing beam; a footing at the bottom of each column; and dampening/stabilizing element(s) to mitigate vibration and uplift.

### FIELD OF THE INVENTION

The instant invention relates to the field of photovoltaic building and deployment systems, specifically to a modular structure for supporting a solar energy conversion system. The present invention is particularly, but not exclusively, useful as a modular structure for supporting photovoltaic systems to convert solar energy into electricity and to provide shade to an area, such as a carport.

### BACKGROUND OF THE INVENTION

After analyzing the field of designing, manufacturing, and marketing various solar-related products for nearly a decade, the instant invention has been designed and developed to overcome deficiencies observed with the prior art, as discussed hereinbelow.

Due to the depletion of known reserves of fossil fuels, much research and development has gone into searching for alternative energy sources. One source of alternative energy is solar energy. As a renewable source, solar energy is increasingly popular for use as an electricity source. One method of converting solar energy to electricity involves photovoltaic energy systems. Such systems use solar cells or solar photovoltaic arrays to convert solar energy directly into electricity.

Solar power or solar energy comprises technologies that obtain energy from the light of the sun and have been utilized for a number of known applications, including lighting, heating for hot water heaters, building heat, cooking, electricity generation, salt water desalination and the like.

Photovoltaics are generally based upon solar cells which employ the photovolatic effect of semiconductors to generate electricity from sunlight. Such “trickle charge” devices are known to produce DC power, dependent upon the area of the plate and the transparency of the glass covering. Substituting renewable energy sources for non-renewable energy sources helps to reduce the harmful ecological impact of fossil fuels.

Current practice for construction of solar structures, such as solar carports, for example, is based on conventional carport construction, which essentially incorporate variations on post-and-beam support systems. These platforms typically provide protection from the sun, particularly in areas of high solar gain, as well as protection from the elements, such as rain, snow, and hail. Typically, this construction is limited in span, sheltering only two (2) to four (4) vehicles per bay, in either two (2) or (4) post bay construction, in a linear span of approximately 30 feet.

Current construction of solar carports is essentially a typical roofed carport structure, which also supports solar panels. In such constructions, solar panels are simply added to the roof of a conventional carport. However, the columns of existing carports are impediments when moving a vehicle in or out of the carport, and further frustrate the removal of snow, for example. Reducing the number of columns requires deeper beams to provide longer spans. This approach, however, is inherently over-designed for use as a solar infrastructure. It has been recognized by the inventors of the present invention that using long spans to reduce the number of columns necessary to support the structure alleviates the problems caused by the use of two (2) or (4) post bay construction. Further, the solar panels become the roof, further reducing the structural requirements. Accordingly, it is an object of the present invention to provide a low cost, long span structure with a universal armature for support of a multiplicity of solar panels.

Current practice for construction of ground arrays utilize a post and beam or a “tree” system with numerous footings. This approach, however, creates obstacles for vehicles. The use of a cable-stayed structure would reduce the structural support requirements. It is therefore an object of the present invention to provide a solar ground mount system which, as noted above, reduces the number of footings and provides a low cost, universal structure.

As observed, conventional solar carports utilize solar panels on the existing roof of the carport. See, for e.g., U.S. Pat. No. 4,373,308 to Wittaker, U.S. Pat. No. 4,718,404 to Sadler, U.S. Pat. No. 4,867,133 to Sadler, U.S. Pat. No. 5,143,556 to Matlin, U.S. Patent Pub. No. 2006/0086382 A1 to Plaisted, and U.S. Pat. No. Des. 408,554 to Dinwoodie. However, such designs add weight to roof thereby compromising the ability of the structure to support both the roof, and the added weight of the solar panels. It is therefore an object of the present invention to provide a solar carport platform, which also functions to provide environmental protection, by providing solar panels which themselves form the roof of the structure. It is a further object of the present invention to provide a structure which utilizes solar panels to form the structure of the roof, which provides shelter while simultaneously generating electricity.

Conventional solar carports known in the art require that the carport be installed on level ground or terrain, and cannot be deployed in areas with uneven terrain or culvert and drainage/retention basins. Accordingly, it is an object of the present invention to provide a structure which can be readily deployed on surfaces which are not level. Providing a structure which can be deployed on both uneven and even terrain allows the end-user to position the structure in an area with maximum solar exposure, despite the evenness of the terrain.

In that it is the underlying objective of current national solar program policy to develop “grid parity” with conventional power generation, it is an object of the present invention to provide a carport which provides for grid parity with conventional power generation. Indeed, the present invention may function to reduce the strain on a local power grid by supplying power to adjacent parking lot lights, for example, with energy generated by the structure. Alternatively, the energy generated by the structure may be sent directly to a utility company or corresponding power grid and distributed to other users within the grid.

It is also an object of the present invention to provide a carport which can be used for military applications. Indeed, as discussed below, the present invention may be pre-fabricated or modular, thus allowing the end-user to quickly deploy the structure and to modify the same according to the desired use. Further, it is envisioned that the carport of the present invention may be utilized to provide both shade from the sun and light from an electrical source, such as a lamp known in the art, for example.

Other objects of the instant invention will be observable through a complete study of the specification, drawings and claims herein. Objects of the instant invention are provided as examples and are not intended to be limitive of the scope of the protection herein.

### SUMMARY OF THE INVENTION

The various features of novelty which characterize the invention are pointed out with particularity in the claims annexed to and forming a part of the disclosure. For a better understanding of the invention, its operating advantages, and specific objects attained by its use, reference should be had to the drawings and descriptive matter in which there are illustrated and described preferred embodiments of the invention.

One embodiment of the present invention involves a cable reinforced matrix for support of a photovoltaic solar panel array comprising array bracing beams which define a perimeter of a matrix array including at least two longitudinal array bracing beams and at least two latitudinal array bracing beams with coupling apertures at various points along said latitudinal array bracing beams; at least one cable coupling at opposite points along the latitudinal array bracing beams; cabling traversing the latitudinal array bracing beams secured by the cabling couplings; at least one solar panel element atop the cabling; longitudinal frame I-beams between the longitudinal array bracing beams and the solar panel element(s); latitudinal frame I-beams between the latitudinal array bracing beams and the solar panel element(s); at least one interpanel I-beam between two adjacent solar panel elements; a plurality of grommets along the cabling; a plurality of grommet clips encompassing the grommets; a plurality of grommet clip fasteners configured to hold the grommets within the grommet clips; a plurality of panel fasteners configured to mate with the grommet clips to secure the solar panel elements; at least one column at either end of the longitudinal array bracing beams; a first cantilever support post extending from the column to the distal portion of the longitudinal array bracing beam; a second cantilever support post extending from the column to the proximal portion of the longitudinal array bracing beam; and a footing at the bottom of each column to anchor the columns.

The present invention relates to long span, cable-stayed structures for elevated support of photovoltaic solar panels and equipment, which may be utilized to provide longer span, lower cost armature for panel support wherein the photovoltaic solar panels themselves became the roof (such as in the case of solar carports). In particular, the present invention follows the evolution of long-span bridge design which has relied on the characteristics of high tension cable suspension and post-tensioning to reduce the number of supports. Structures known in the art which utilize photovoltaic solar panels to enclose a roof a structure fail to provide any means to provide a longer span. See, for example, U.S. Patent Pub. No. 2009/0050194 A1 by Nobel et al.

Structures such as carports, parking garages, and aircraft hangers require greater open areas between columnar supports that are often greater than standard wood or steel structural members can span. Designs for long span structures may be chosen depending on the area to be spanned, the anticipated roof loads, occupancy use, etc. For example, bar joists, trusses, space frames, and folded shell structures may be utilized to lengthen the span of a structure. The overall span of the structure may be modified based upon, for example, the number of cars desired to be parked under the structure, the desired number of columns, etc. The structure of the present invention is configured to enable the safe employment of relatively long reaches between columns so as to minimize the overall column count, thus allowing ample space for an automobile or other large vehicle, for example, to move readily in and out of the structure.

In one embodiment of the present invention, the structure includes footings at endpoints to anchor the structure of the present invention to the desired terrain. The present invention includes interpanel I-beams to allow flex. The inherent flexibility of the present invention allows for minor changes in span, while also allowing the solar panels displaced atop the structure to move without damaging the solar panels, which typically include glass or other inflexible materials. Such flexibility also allows for last minute changes to be made, without complete reengineering. Indeed, the post-tensioned cable system of the present invention enables adaptability for spaces which may vary from 7′6″ to 10′ or more to varying lengths. One of ordinary skill in the art will recognize, on reading the disclosure of this invention, that the principles and fundamental architectural structure of this invention are independent of selected dimensions. The objective of the present invention is to provide a low cost, unencumbered space/shelter, adaptable to various parking modules and uneven terrain with the inherent features of speed of deployment, portability and demountability.

In one embodiment, the structure of the present invention is pre-fabricated, to allow for quick deployment. By permitting quick deployment, the system of the present invention is useful in both conventional applications as well as emergency and military operations. The system of the present invention is frangible, which is particularly useful in military applications, wherein objects are subject to explode.

In another embodiment, the structure of the present invention is modular, to allow for portability. It is envisioned that such a modular structure would be useful for military or emergency operations, for example, as it can be adapted based on the area for deployment, the number of vehicles to be covered, the amount of energy required, etc.

The structure of the present invention includes a grommet clip connection between the cables and photovoltaic solar panels at four (4) or more points, with cross-bracing at each panel. The grommet clips are preferably comprised of steel and rubber, which allow the clips to securely clamp, clip, or connect the solar panel to the cable. However, it will be recognized by one of ordinary skill in the art that the grommet clip connection may be fabricated from any material known in the art. Providing grommet clips to connect the solar panel(s) to the cable provides resistance to wind uplift. In one embodiment of the present invention, the spacing of the cables equals the width of the solar panel, which allows the solar panels to be arrayed in either portrait or landscape mode. In another embodiment of the present invention, velcro or metal velcro, such as Metaklett, is used to connect the solar panel(s) to the cable. In that embodiment, the hook portion of the velcro or metal velcro hook-and-loop fastening system is affixed to the solar panel(s), while the loop portion of the velcro or metal velcro hook-and-loop fastening system is affixed to the cable. In another embodiment, the loop portion of the velcro or metal velcro hook-and-loop fastening system is affixed to the solar panel(s), while the hook portion of the velcro or metal velcro hook-and-loop fastening system is affixed to the cable.

Rubber I-beams are disposed between photovoltaic panels to make the roof of the structure waterproof. It is envisioned, however, that the I-beams may be constructed of any material that provides a waterproof roof for the structure. Waterproof roofs for carports are especially desirable in areas which will be used as charging stations or where shelter from the elements is a higher priority. Furthermore, rubber I-beams are disposed between photovoltaic solar panels to allow some degree of flexibility between the solar panels, which prevents the solar panels from being damaged. For example, disposing rubber I-beams between photovoltaic solar panels provides a dampening function against expansion/contraction and harmonic vibration. It is envisioned, however, that the I-beams may be constructed of any material that provides a dampening function against expansion/contraction and harmonic vibration, such as, for example, latex, asphaltic mastic sheets, viscoelastic sprayable liquid, viscoelastic dampening polymers, vibration dampening bushings and vibration dampening tiles.

In one particular embodiment of the present invention, velcro or metal velcro, such as Metaklett, is disposed between the solar panels to connect the same. In that embodiment, the hook portion of the hook-and-loop fastening system is affixed to one solar panel, while the loop portion of the velcro or metal velcro hook-and-loop fastening system is affixed to the solar panel to be joined. In another embodiment, the loop portion of the velcro or metal velcro hook-and-loop fastening system is affixed to the solar panel(s), while the hook portion of the velcro or metal velcro hook-and-loop fastening system is affixed to the cable having the loop portion of the velcro or metal velcro hook-and-loop fastening system.

A modular base cable harness is connected to anchored end “T” or mass wall supports. In one embodiment of the present invention, eccentric footings are provided for the supports.

The system of the present invention utilizes a mid-span dampening element called “ALICE” which functions to dampen harmonic vibration, as well as to minimize deflection and uplift. ALICE also functions as a platform for a combiner box, lighting control, battery, security camera, and data acquisition storage. In one embodiment of the present invention, the base of the post is a sandwich of at least two (2) steel plates with compressible spring-diaphragms. In this embodiment, the steel plate of the lower part of the post includes a steel tether, which is preferably about 12″ in diameter, to limit upward movement in extremely high wind conditions. In another embodiment of the present invention, the base of the post is a hydraulic armature bolted through to a concrete base.

In one embodiment of the present invention, ALICE (one acronym) includes an elevated mount for equipment, which functions include options for Alignment, Lighting, Combiner box, Energizing (such as an electric charging station for electric vehicles), as well as data acquisition.

In one embodiment of the present invention, a composite end girder is provided to provide a high strength-to-weight ratio beam at the edges, which will allow for a molding with alternative style treatments.

In another embodiment of the present invention, a lighting housing is provided which includes concealment of conduit for wiring. Concealing the conduit wiring within a housing for lighting prevents the wiring from being exposed to the elements, thus prolonging the life of the wiring, while ensuring that the power and control system functions properly.

It is envisioned that the foundation of the present invention can be either fixed or removable, depending on the desired use. In the case of a fixed foundation, an eccentric (inboard) support for steel or concrete walls is provided for supporting the post-tensioned cable harness. Main supports can vary based on local soil conditions, and may feature a concrete post with a cantilevered grade beam set inboard on each end support point. Alternatively, tension rods may be tethered to a heavy weight from each end support point. The concrete base of the ALICE unit includes at least four (4) steel rods, set at an oblique angle from grade, which provides resistance to upward movement. In the case of a removable foundation, such as those used in military applications and the like, a pre-cast base is set on grade to serve as a counter-weight support for an angled post in order to serve as a base support for an inverter. The cable armature is fastened to a horizontal truss, which is itself fastened to the angled column support and vertically connected via a steel tie rod.

The present invention is especially well suited for large parking lots and parking garages and provides the benefit of protecting parked vehicles from sunlight and other elements, while simultaneously providing electrical generating and/or an alternate power supply. Therefore, the present invention may function to reduce the strain on a local power grid by supplying power to adjacent parking lot lights or electric batteries, for example, with energy generated by the structure. Alternatively, the energy generated by the structure may be sent directly to a utility company or corresponding power grid and distributed to other users within the grid.

As used herein, the term photovoltaic solar panel or solar panel refers to a combination of a sheet of transparent material or other lamina, an array or group of photovoltaic cells interconnected to provide an output of electrical energy, and any backing sheet or material, which forms a device capable of transforming incident radiation to electrical current. Such panels are traditionally comprised of a transparent front or radiation-facing sheet such as a glass or transparent polymer, laminated with layers of transparent conductors, photovoltaic materials, cell-connecting circuits, metals and other lamina which together comprise an operative photovoltaic panel. Thus, photovoltaic panels have traditionally included a sheet of glass or other rigid transparent material to protect the photovoltaic cell, and a back sheet of steel or aluminum metal or foil, with the various lamina being bonded together by a dielectric layer of plasticized polyvinyl butyryl or ethylene vinylacetate. In instances where a totally transparent photovoltaic panel is desired, a front and back sheet both of rigid transparent material is employed. It is envisioned that the structure of the present invention may use any solar panel(s) known in the art. As used in the present invention, the photovoltaic panels are integral or dispersed in the roof of the carport, or, alternatively, constitute the roof of the carport itself.

Other features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims.

### BRIEF DESCRIPTION OF THE DRAWINGS

In the drawings, wherein similar reference characters denote similar elements through the several views:

FIG. 1 is an environmental view of one embodiment of the present invention.

FIG. 2 is a side view of one embodiment of the present invention.

FIG. 3 is a side view of the lighting element of the present invention.

FIG. 4 is a side view of the lighting element of the present invention.

FIG. 5 is a close up view of one embodiment of the present invention.

FIG. 6 is an environmental view of the grommet clip assembly of the present invention.

FIG. 7 is an environmental view of the individual elements of the grommet clip assembly of the present invention.

FIG. 8 is an environmental view of one embodiment of the present invention showing the interface between the cabling, cable coupling, and lateral array bracing beam.

FIG. 9 is a side view of one embodiment of the present invention showing solar panel elements and grommet clip assemblies of the present invention.

FIG. 10 is a side view of one embodiment of the present invention showing solar panel elements and grommet clip assemblies of the present invention.

FIG. 11 is an environmental view of one embodiment of the present invention.

FIG. 12 is a side view of one embodiment of the present invention.

FIG. 13 is an environmental view of one embodiment of the present invention showing the column and footing of the present invention.

FIG. 14 is an environmental view of a preferred embodiment of the present invention.

FIG. 14a is an environmental view of one embodiment of the present invention, showing the column, post support, connector assembly and cantilever bracing assembly of the present invention.

FIG. 15 is an environmental view of one particular embodiment of the present invention.

### DETAILED DESCRIPTION OF THE PREFERRED EMBODIMENTS

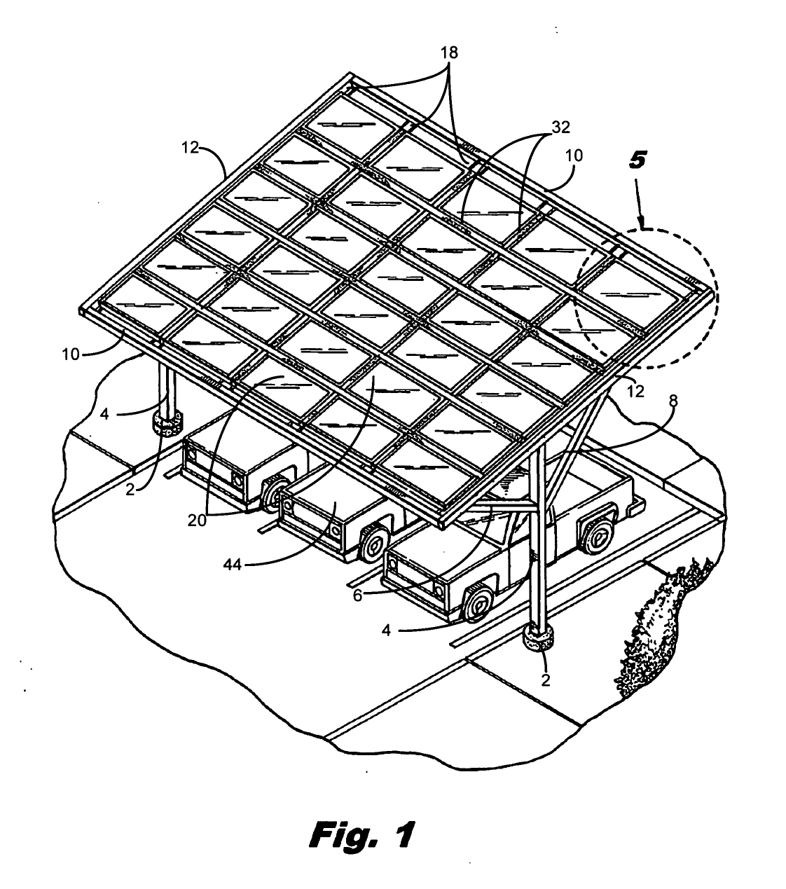

In accordance with the subject invention, FIG. 1 shows one embodiment of the present invention in which a plurality array bracing beams define a perimeter of a matrix array. In this embodiment, the array bracing means include at least two longitudinal array bracing beams 12 and at least two latitudinal array bracing beams 10. It will be recognized by one of ordinary skill in the art that the number of longitudinal array bracing beams 12 and latitudinal array bracing beams 10 may be varied based upon the desired configuration of the cabled matrix of the present invention. For example, the number of longitudinal array bracing beams 12 and latitudinal array bracing beams 10 may be varied based upon the number of sides in the cabled matrix.

Latitudinal array bracing beams 10 include coupling apertures 50 at various points along each latitudinal array bracing beam 10. In one particular embodiment of the present invention, coupling apertures 50 are disposed at opposing points on latitudinal array bracing beams 10, such that one coupling aperture 50 on one (1) latitudinal array bracing beam 10 is directly opposite another coupling aperture 50 on another latitudinal array bracing beam 10. Coupling aperture 50 may be threaded, as shown in FIG. 8, to receive another threaded element, such as a bolt. It should be appreciated by one of ordinary skill in the art that coupling aperture 50 may be indented so as to receive an element of corresponding size and shape to the indent. For example, the indent of coupling aperture 50 may be rounded to receive a round element, which would then be press-fit into coupling aperture 50 to hold such element within the indent of coupling aperture 50.

Cable coupling 40 is received at opposite points along latitudinal array bracing beams 10, and is configured to fit within coupling aperture 50, as shown in FIG. 8. In one particular embodiment of the present invention, one cable coupling 40 is directly opposite another cable coupling 40. Cable coupling 40 may be threaded at the distal end thereof, as shown in FIG. 8, to receive fit within coupling aperture 50, which has corresponding threading. It should be appreciated by one of ordinary skill in the art that the distal end of cable coupling aperture 40 may configured to correspond to the size and shape of coupling aperture 50. For example, the indent of coupling aperture 50 may be rounded to receive cable coupling 40 with a distal end which is rounded, which would then be press-fit into coupling aperture 50 to hold cable coupling 40 within coupling aperture 50.

Cabling 18 traverses latitudinal array bracing beams 10 and is secured by cabling couplings 40, to hold cabling 18 in place in its desired position along latitudinal array bracing 10. Installing a plurality of cabling 18 provides a cable matrix forms an open roof, which is capable of supporting additional elements. In a preferred embodiment of the present invention, cabling 18 is braided steel. However, it is understood by one of ordinary skill in the art that cabling 18 may be manufactured of any material, or combination of materials, sufficient to form an open roof and support additional elements such as, for example, copper, tinned copper, aluminum, bronze, tinned cadmium bronze, stainless steel, nylon cord, aramid fiber cord, kevlar fiber cord, insulated fibrous cord, flooded steel messenger, steel messenger, galvanized steel messenger, and aircraft wire.

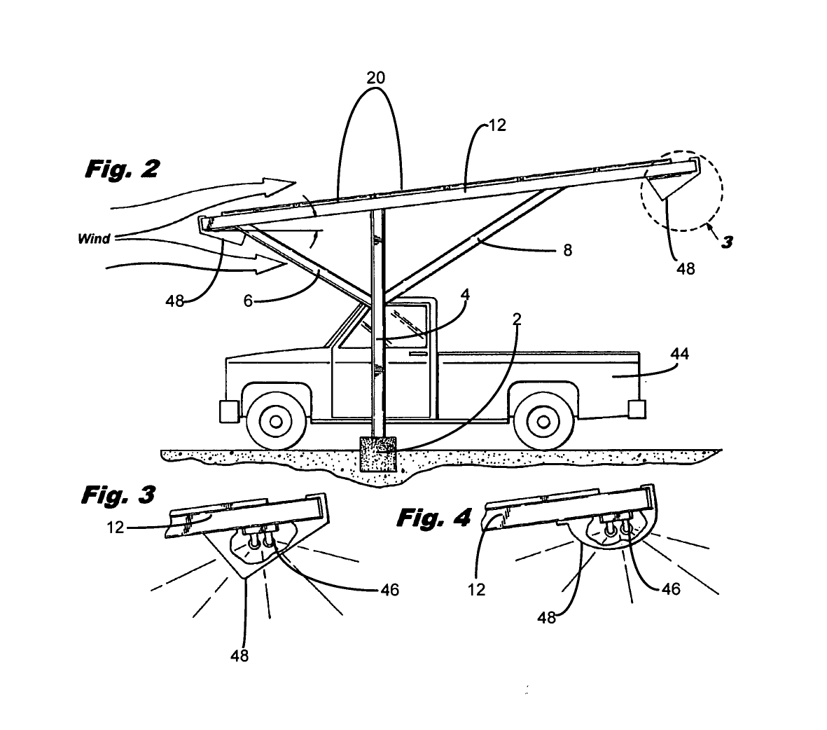

As shown in FIGS. 2-4, a preferred embodiment of the present invention includes a lighting element 46 at opposite ends of longitudinal array bracing beams 12 and/or latitudinal array bracing beams 10. In this embodiment, lighting element 46 is illuminated using power generated from solar panel elements 20. It is envisioned that solar panel elements 20 will produce more energy than lighting element 46 consumes, thus allowing the surplus energy generated by solar panel elements 20 to be used for other applications, or sold back to a utility company. In one particular embodiment, lighting element 46 includes a cover 48 corresponding to each lighting element 46. In particular, cover 48 is configured to protect lighting element 46 from the elements. In one embodiment of the present invention, cover 48 forms a watertight seal with longitudinal array bracing beam 12 and/or latitudinal array bracing beam 10, which prevents moisture from entering.

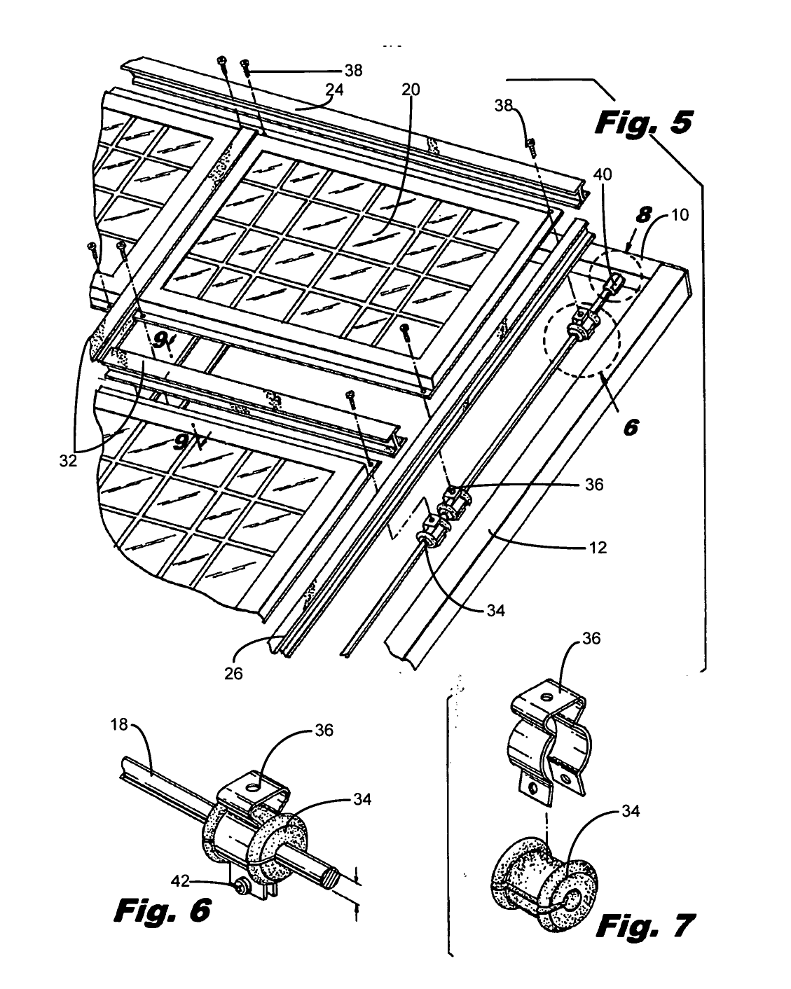

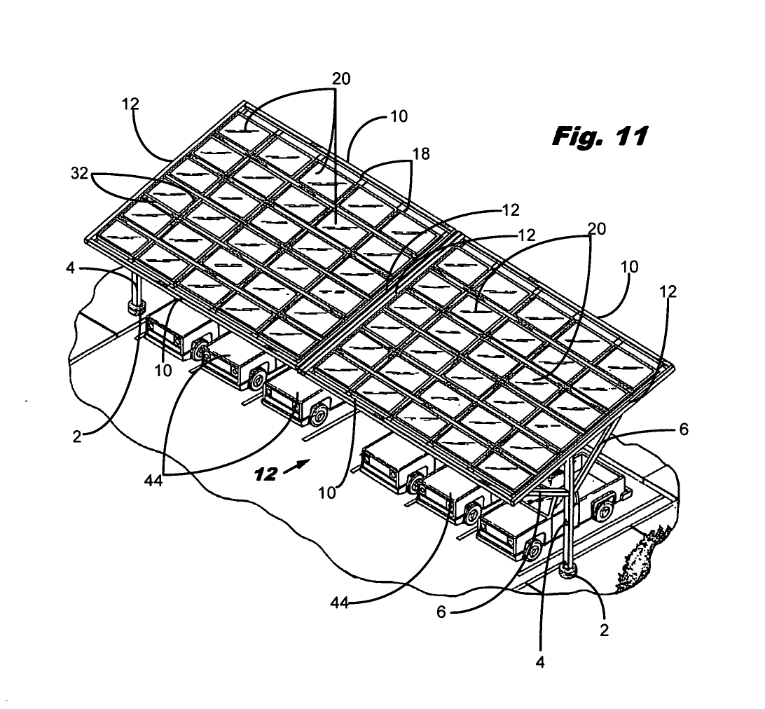

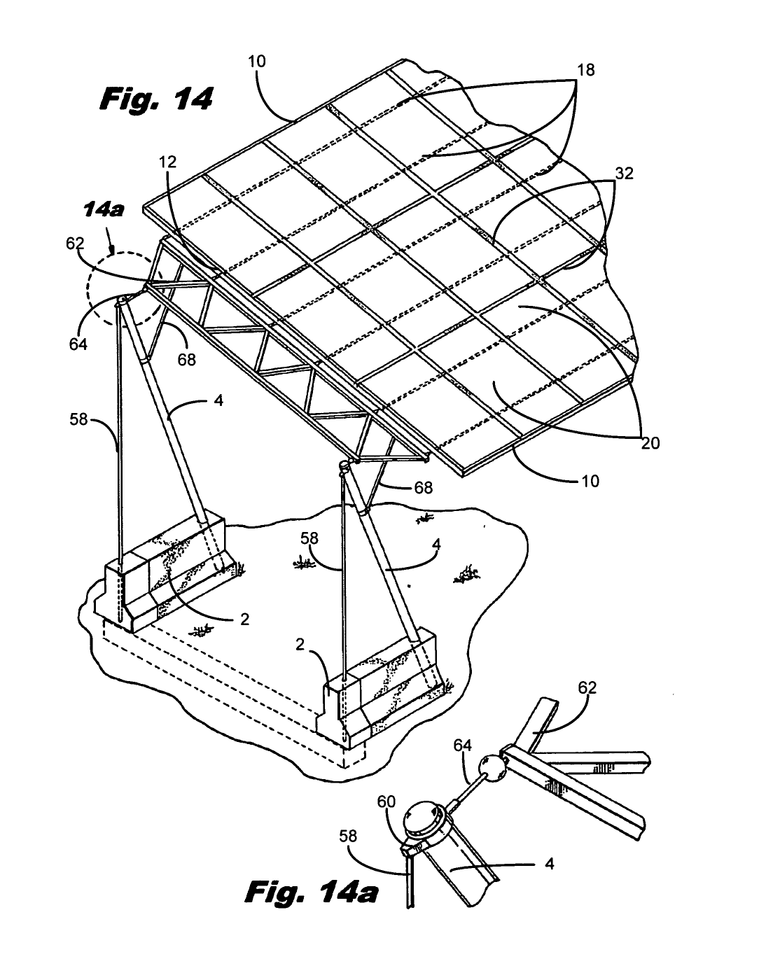

As shown in FIG. 5, at least one solar panel element 20 is placed atop cabling 18. Cabling 18 is placed at various positions along latitudinal array bracing beams 10 so as to fully support each solar panel element 20. One of ordinary skill in the art will appreciate that cabling 18 may be placed near the edge of each solar panel element 20. Alternatively, cabling 18, may be placed towards the center of each solar panel element 20. Allowing the end-user to determine where to place cabling 18 and the number of cablings 18 provides the ability to position solar panel element 20 in either a landscape or portrait format. As shown in FIG. 1 and FIG. 11, for example, solar panel elements 20 are in landscape format. As shown in FIG. 14, solar panel elements 20 are in portrait format.

As shown in FIG. 5, longitudinal frame I-beams 26 are disposed between longitudinal array bracing beams 12 and solar panel element(s) 20. Latitudinal frame I-beams 24 are disposed between latitudinal array bracing beams 10 and solar panel element(s) 20. In particular, when assembled, longitudinal frame I-beams 26 and latitudinal frame I-beams 24 form a perimeter which fit within the matrix array formed by the array bracing means. One of ordinary skill in the art will recognize that longitudinal frame I-beams 26 and latitudinal frame I-beams 24 will provide a dampening effect, which will protect solar panel elements 20 from breaking, should solar panel elements 20 move, due to wind, for example. Furthermore, longitudinal frame I-beams 26 and latitudinal frame I-beams 24 prevents water from entering between longitudinal frame I-beams 26, latitudinal frame I-beams 24, and solar panel elements 20. In one particular embodiment of the present invention, longitudinal frame I-beams 26 and latitudinal frame I-beams 24 are made of rubber. However, it will be understood by one of ordinary skill in the art that longitudinal frame I-beams 26 and latitudinal frame I-beams 24 may be made of any material know in the art which provides for the desired dampening and water resistant characteristics.

At least one interpanel I-beam 32 is provided to allow for dampening and water resistance around each solar panel element 20. In one particular embodiment of the present invention, interpanel I-beam 32 is made of rubber. However, it will be understood by one of ordinary skill in the art that interpanel I-beam 32 may be made of any material know in the art which provides for the desired dampening and water resistant characteristics.

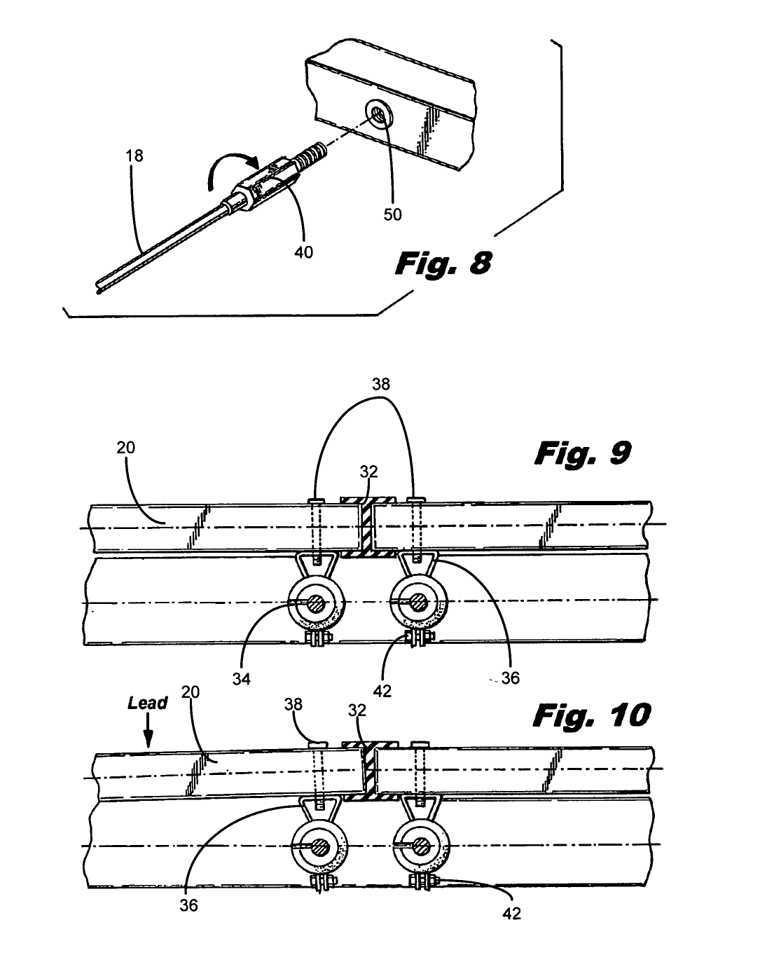

To secure solar panel elements 20 to the cable matrix array, a plurality of grommets 34 are provided along cabling 18, as shown in FIGS. 6-7. A plurality of grommet clips 36 surround grommets 34. A plurality of grommet clip fasteners 42 are configured to hold grommets 34 within grommet clips 36. Grommets 34, grommet clips 36 and grommet clip fasteners 42 form a grommet assembly. A plurality of panel fasteners 38 a provided to mate with the top portion of grommet clips 36 to secure solar panel elements 20 to the cable matrix array. In a preferred embodiment of the present invention, panel fasteners 38 are inserted downwardly into an aperture on the top portion of grommet clip 36, as shown in FIGS. 5, 9 and 10. However, it is understood by one of ordinary skill in the art that panel fasteners 38 may be inserted into any aperture on grommet clip 36.

At least one column 4 is provided at either end of longitudinal array bracing beams 12. A first cantilever support post 6 extends from column 4 to the distal portion of longitudinal array bracing beam 12. In one particular embodiment of the present invention, the angle between column 4 and first cantilever support post 6 is an acute angle. However, it is understood by one of ordinary skill in the art that the angle between column 4 and first cantilever support post 6 may be of any degree, depending on the desired pitch of the roof structure. A second cantilever support post 8 extends from column 4 to the proximal portion of longitudinal array bracing beam 12. In one particular embodiment of the present invention, the angle between column 4 and second cantilever support post 8 is an acute angle. However, it is understood by one of ordinary skill in the art that the angle between column 4 and second cantilever support post 8 may be of any degree, depending on the desired pitch of the roof structure.

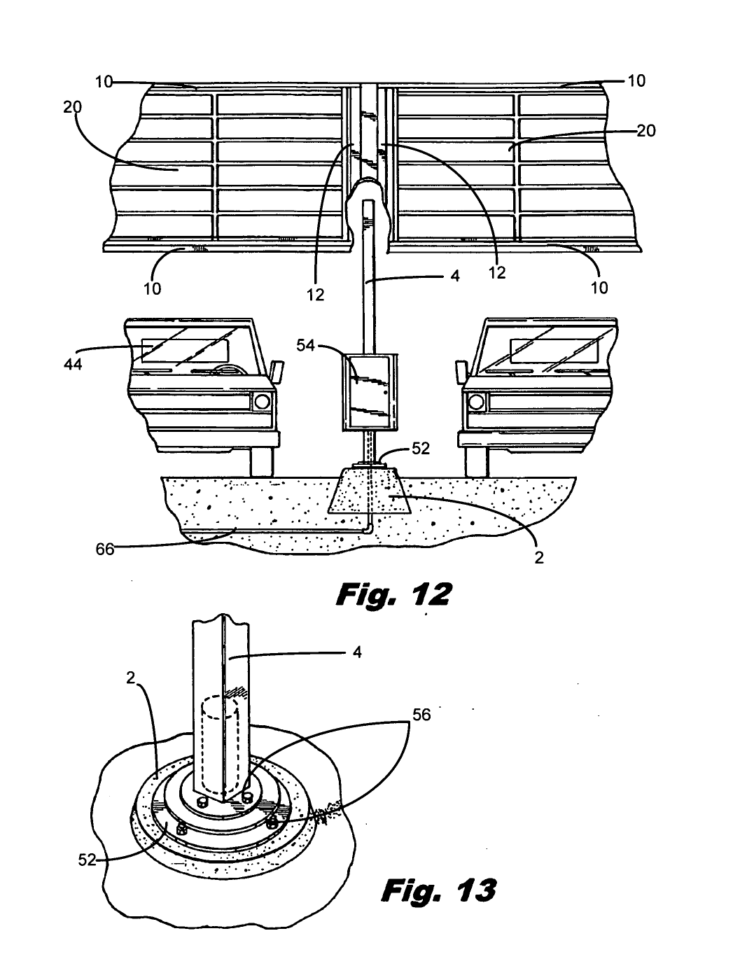

In one particular embodiment of the present invention, as shown in FIG. 12, a housing 54 is included along column 4. In that embodiment, wiring 66 is included to provide a means to provide electricity to and from housing 54 and solar panel element(s) 20.

Footing 2 is disposed at the bottom of each column 4 to anchor columns 4. In a preferred embodiment of the present invention, footing 2 is made of cement. However, footing 2 may be made of any material known in the art to anchor a column. In one particular embodiment of the present invention, shown in FIG. 12, footing 2 is sunken into the ground to provide additional support.

In another embodiment of the present invention, as shown in FIGS. 12-13, a plate 52 is disposed between footing 2 and column 4, to connect column 4 to footing 2. In this embodiment, plate 52 is secured to footing 2 via one or more one or more rivet 56. In particular, rivet 56 is displaced downwardly through plate 52 to secure column 4 to footing 2. However, it will be appreciated by one of ordinary skill in the art that rivet 56 may be fixed in footing 2, and protrude vertically through plate 52. Furthermore, rivet 56 may be threaded, wherein a corresponding threaded element, such as a nut, for example, may be used to secure rivet 56 to plate 52.

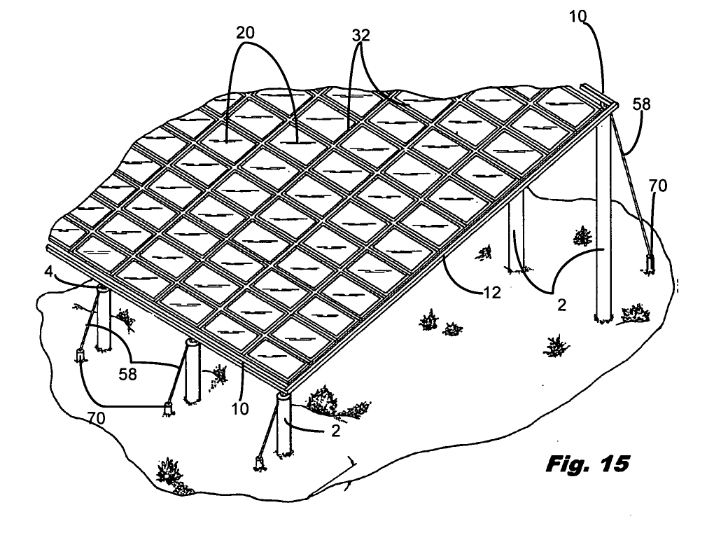

In a preferred embodiment of the present invention, as shown in FIGS. 14 and 14a, the cable reinforced matrix for support of a photovoltaic solar panel array includes a post support 58 extending from footing 2 to column 4. In this embodiment, a cantilever bracing assembly 62 is disposed between column 4 and longitudinal array bracing beams 12. A connector assembly 64 connects column 4 and cantilever bracing assembly 62. Cantilever bracing assembly 62 is further supported by support 68. As shown in FIG. 15, column 4 may be further supported by post support footing 70.

While there have been shown, described and pointed out fundamental novel features of the invention as applied to preferred embodiments thereof, it will be understood that various omissions and substitutions and changes in the form and details of the device illustrated and in its operation may be made by those skilled in the art without departing from the spirit of the invention. It is the intention, therefore, to be limited only as indicated by the scope of the claims appended hereto.

I claim:

1. A cable reinforced matrix for support of a photovoltaic solar panel array comprising:
(a) array bracing beams which define a perimeter of a matrix array including:
(1) at least two longitudinal array bracing beams; and
(2) at least two latitudinal array bracing beams with coupling apertures at various points along said latitudinal array bracing beams;
(b) at least one cable coupling at opposite points along said latitudinal array bracing beams;
(c) cabling traversing said latitudinal array bracing beams secured by said cabling couplings;
(d) at least one solar panel element atop said cabling;
(e) longitudinal frame I-beams between said longitudinal array bracing beams and said solar panel element(s);
(f) latitudinal frame I-beams between said latitudinal array bracing beams and said solar panel element(s);
(g) at least one interpanel I-beam between two adjacent solar panel elements;
(h) a plurality of grommets along said cabling;
(i) a plurality of grommet clips encompassing said grommets;
(j) a plurality of grommet clip fasteners configured to hold said grommets within said grommet clips;
(k) a plurality of panel fasteners configured to mate with said grommet clips to secure said solar panel elements;
(l) at least one column at either end of said longitudinal array bracing beams;
(m) a first cantilever support post extending from said column to the distal portion of said longitudinal array bracing beam;
(n) a second cantilever support post extending from said column to the proximal portion of said longitudinal array bracing beam; and
(o) a footing at the bottom of each column to anchor said columns.

2. The cable reinforced matrix for support of a photovoltaic solar panel array of claim 1, wherein said cabling is braided steel.

3. The cable reinforced matrix for support of a photovoltaic solar panel array of claim 1, further comprising a lighting element at opposite ends of said longitudinal array bracing beams and/or said latitudinal array bracing beams.

4. The cable reinforced matrix for support of a photovoltaic solar panel array of claim 3, further comprising a cover corresponding to each lighting element.

5. The cable reinforced matrix for support of a photovoltaic solar panel array of claim 1, further comprising a plate between said footing and said column, configured to connect said column to said footing.

6. The cable reinforced matrix for support of a photovoltaic solar panel array of claim 1, further comprising at least one rivet to secure said plate between said footing and said column.

7. The cable reinforced matrix for support of a photovoltaic solar panel array of claim 1, further comprising a housing along said column.

8. The cable reinforced matrix for support of a photovoltaic solar panel array of claim 7, further comprising wiring to and from said housing and said solar panel element(s).

9. The cable reinforced matrix for support of a photovoltaic solar panel array of claim 1, further comprising a post support extending from said footing to the top portion of said column.

10. The cable reinforced matrix for support of a photovoltaic solar panel array of claim 9, further comprising a cantilever bracing assembly between said column and said longitudinal array bracing beams.

11. The cable reinforced matrix for support of a photovoltaic solar panel array of claim 10, further comprising a connector assembly connecting said column and said cantilever bracing assembly.

12. The cable reinforced matrix for support of a photovoltaic solar panel array of claim 9, further comprising a post support footing.
